(19) United States
(12) Patent Application Publication
(10) Pub. No.: US 2021/0180599 A1
(43) Pub. Date: Jun. 17, 2021

(54) VACUUM PRESSURE CONTROL SYSTEM

(71) Applicant: CKD CORPORATION, Komaki-shi (JP)

(72) Inventor: Yutaro HAYASE, Komaki-shi (JP)

(73) Assignee: CKD CORPORATION, Komaki-shi (JP)

(21) Appl. No.: 17/111,958

(22) Filed: Dec. 4, 2020

(30) Foreign Application Priority Data
Dec. 12, 2019 (JP) 2019-224247

(51) Int. Cl. F04C 28/24; G05D 7/06

(52) U.S. Cl. CPC F04C 28/24; G05D 7/06

(57) ABSTRACT

A vacuum pressure control system that can easily calculate an optimum valve open degree of a vacuum control valve for making a pressure value of a vacuum chamber agree with a target value is provided. A controller approximates a relation between the pressure value in the vacuum chamber and a flow rate of process gas to linear functions, and the system includes a mapping program and a valve-open-degree calculation program stored in the controller to calculate the optimum valve open degree of the vacuum control valve for making the pressure value in the vacuum chamber agree with the target value based on the linear functions when the process gas at the predetermined flow rate is supplied. The valve open degree of the vacuum control valve is adjusted based on the optimum valve open degree so that the pressure value in the vacuum chamber is made agree with the target value.

### CROSS-REFERENCE TO RELATED APPLICATIONS

This application is based upon and claims the benefit of priority from the prior Japanese Patent Application No. 2019-224247 filed on Dec. 12, 2019, the entire contents of which are incorporated herein by reference.

### BACKGROUND

### Technical Field

The present disclosure relates to a vacuum pressure control system including a gas supply source, a vacuum chamber to be supplied with gas from the gas supply source, a vacuum control valve to adjust a pressure value in the vacuum chamber, and a vacuum pump to decompress the vacuum chamber, which are connected in series, and further including a pressure sensor to detect the pressure value in the vacuum chamber and a controller to control the vacuum control valve. The vacuum pressure control system is configured such that the controller adjusts a valve open degree of the vacuum control valve based on the pressure value detected by the pressure sensor to perform a pressure-value control of controlling the pressure value in the vacuum chamber to be a target value.

### Related Art

Heretofore, as described in JPH10(1998)-252942, there is adopted a vacuum pressure control system configured to adjust a pressure value in a vacuum chamber to be a target pressure value and to retain that pressure value. This type of vacuum pressure control system is, for example, used for deposition on a wafer as a material for a semiconductor. Specifically, the pressure value of the vacuum chamber to be supplied with gas (process gas) at a flow rate required for deposition is maintained to a target value by adjusting a valve open degree of the vacuum control valve, and then deposition on the wafer that is placed in the vacuum chamber is performed.

### SUMMARY

### Technical Problems

However, the above-mentioned conventional technique has the following problem. As mentioned above, in order to maintain the pressure value in the vacuum chamber to be at the target value, the valve open degree of the vacuum control valve has to be adjusted to an optimum state. This optimum valve open degree of the vacuum control valve is, however, determined once after performing the actual pressure value control. Accordingly, as an advance preparation for the actual deposition process, there is a need to perform a process of experimentally supplying the process gas at a flow rate necessary for deposition so as to adjust the valve open degree of the vacuum control valve and to find the optimum valve open degree of the vacuum control valve at which the pressure value of the vacuum chamber agrees with the target value. For example, as shown in FIG. 10, an optimum valve open degree VO equal to the target value Pt is searched by gradually narrowing the valve open degree.

Further, the thus searched optimum valve open degree VO is used for confirming whether the actual pressure value of the vacuum chamber agrees with the target value Pt. For example, as shown in FIG. 11, a pressure waveform is confirmed to see whether the pressure value of the vacuum chamber is actually the target value Pt on condition that the valve open degree of the vacuum control valve is set to the optimum valve open degree VO. After completion of this confirmation operation, a deposition process is performed.

Further, in most cases of the deposition process, deposition is performed under plural conditions such as utilizing several types of process gas or utilizing the same type of process gas for several times but at different flow rates and at different target pressure values in each time in one unit of process. Accordingly, there is a need to perform the above-mentioned operation of searching the optimum valve open degree and the above-mentioned operation of confirming whether the actual pressure value of the vacuum chamber agrees with the target value under all the plural conditions. These advance preparations prior to the deposition process take time as types of process gas to be used increase, which may cause a bad influence on a semiconductor manufacturing efficiency.

The present disclosure has been made to solve the above problem and has a purpose of providing a vacuum pressure control system achieving easy calculation of an optimum valve open degree of a vacuum control valve that is necessary for making a pressure value of the vacuum chamber agree with a target value.

### Means of Solving the Problems

To solve the above problem, the vacuum pressure control system of the present disclosure has the following configuration.

There is provided a vacuum pressure control system comprising: a gas supply source; a vacuum chamber configured to receive supply of gas from the gas supply source; a vacuum control valve configured to adjust a pressure value in the vacuum chamber; and a vacuum pump configured to decompress the vacuum chamber, which are connected in series, the vacuum pressure control system further comprising: a pressure sensor configured to detect the pressure value in the vacuum chamber; and a controller configured to control the vacuum control valve, the vacuum pressure control system configured to perform pressure value control of making the pressure value in the vacuum chamber agree with a target value by the controller adjusting a valve open degree of the vacuum control valve based on the pressure value detected by the pressure sensor while the gas is supplied at a predetermined flow rate from the gas supply source to the vacuum chamber, wherein the controller comprises a mapping program and a valve-open-degree calculation program and is configured in advance of performing the pressure value control to: approximate a relation of the pressure value in the vacuum chamber and the gas flow rate to a linear function and storing the linear function in the controller according to the mapping program; and calculate an optimum valve open degree of the vacuum control valve which is necessary for making the pressure value in the vacuum chamber agree with the target value when the gas at the predetermined flow rate is supplied based on the linear function according to the valve-open-degree calculation program, and the controller adjusts the valve open degree of the vacuum control valve based on the optimum valve open degree to make the pressure value in the vacuum chamber agree with the target value.

According to the above-mentioned vacuum pressure control system, the optimum valve open degree of the vacuum control valve which is necessary for making the pressure value in the vacuum chamber agree with the target value can easily be calculated.

The controller includes the mapping program and the valve-open-degree calculation program. According to the mapping program, the relation of the pressure value in the vacuum chamber and the gas flow rate is approximated to the linear function and the linear function is stored in the controller. Then, based on the thus stored linear function, the valve-open-degree calculation program calculates the optimum valve open degree of the vacuum control valve that is necessary for making the pressure value in the vacuum chamber agree with the target value when the gas at the predetermined flow rate is supplied, and thus the valve open degree of the vacuum control valve can be adjusted based on the calculated optimum valve open degree.

The relation of the pressure value in the vacuum chamber and the gas flow rate is approximated to the linear function, and thus the optimum valve open degree can be calculated from the linear function. Accordingly, in a case of performing deposition under plural conditions such as use of several types of gas, there is no need to adjust the valve open degree of the vacuum control valve by experimentally supplying the gas at a flow rate required for the deposition to the vacuum chamber on each of the plural conditions and to perform a searching operation of the optimum valve open degree which allows the pressure value of the vacuum chamber to agree with the target value. Therefore, there is less possibility of taking time for the advance preparations prior to the deposition process to cause a bad influence on the semiconductor manufacturing efficiency.

Herein, the predetermined flow rate represents a flow rate of the gas when the pressure control of the vacuum chamber is actually carried out, and for example, indicates a flow rate of the gas necessary for deposition on a wafer.

According to the vacuum pressure control system of the present disclosure, an optimum valve open degree of a vacuum control valve that is necessary for making a pressure value of a vacuum chamber agree with a target value can easily be calculated.

### BRIEF DESCRIPTION OF THE DRAWINGS

FIG. 1 is an explanatory view showing a configuration of a vacuum pressure control system in the present embodiment;

FIG. 2 is a sectional view of a vacuum control valve used for the vacuum pressure control system in the present embodiment;

FIG. 3 is a block diagram showing a configuration of a controller used for the vacuum pressure control system in the present embodiment;

FIG. 4 is a table illustrating conditions for applying deposition on a wafer;

FIG. 5 is a flow chart showing a mapping program in the present embodiment;

FIG. 6 is a flow chart showing a valve-open-degree calculation program in the present embodiment;

FIG. 7 is a graph showing a relation between a pressure value in a vacuum chamber and a flow rate of process gas when a valve open degree of the vacuum control valve is maintained uniform;

FIG. 8 is a map formed according to the mapping program;

FIG. 9 is a graph for explaining a method of calculating an optimum valve open degree according to a valve-open-degree calculation program;

FIG. 10 is a graph for explaining an operation of searching the optimum valve open degree according to a conventional art; and

FIG. 11 is a graph used for confirming a pressure waveform when the vacuum control valve opens at the optimum valve open degree.

### DETAILED DESCRIPTION OF THE EXEMPLARY EMBODIMENTS

An embodiment of a vacuum pressure control system according to the present disclosure is explained in detail with reference to the accompanying drawings.

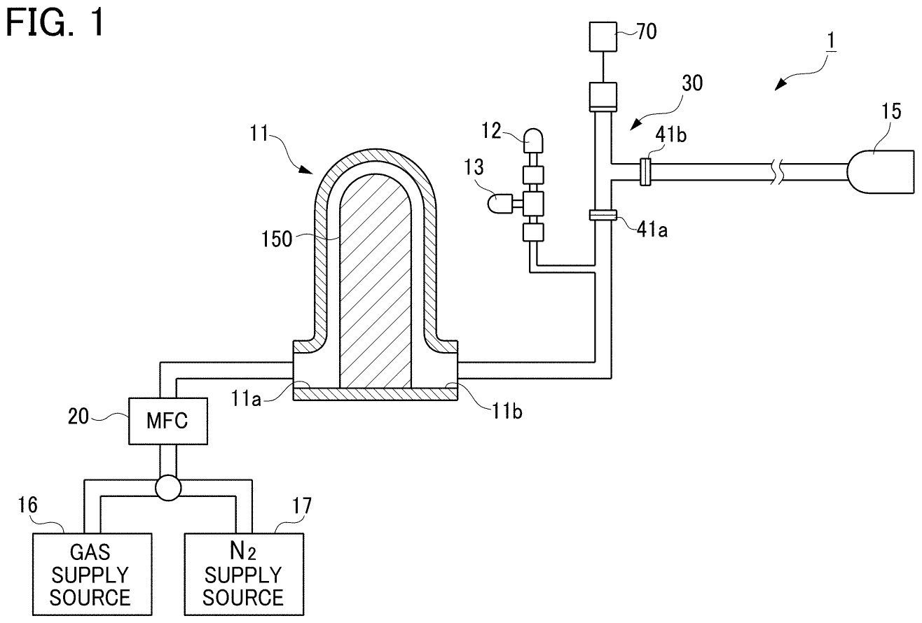

FIG. 1 is a schematic view for explaining a configuration of a vacuum pressure control system 1. The vacuum pressure control system 1 is for example, used for surface processing of a wafer 150 in a semiconductor manufacturing apparatus adopting a method of Atomic Layer Deposition (ALD).

The vacuum pressure control system 1 is, as shown in FIG. 1, configured such that a gas supply source 16 as a supply source of process gas (one example of gas) for surface processing of the wafer 150, a mass flow controller 20, a vacuum chamber 11 as a vacuum container, a vacuum control valve 30, and a vacuum pump 15 are connected in series in this order from an upstream side. Further, on an upstream side of the mass flow controller 20, an N₂ supply source 17 as a supply source of nitrogen gas (N₂) which is used for purging the process gas is connected in parallel with the gas supply source 16.

The vacuum pressure control system 1 further includes a pressure sensor 12 provided between the vacuum chamber 11 and the vacuum control valve 30 via a shut-off valve 13 to detect a pressure value of the vacuum chamber 11 and includes a controller 70 which is electrically connected to the pressure sensor 12 and the vacuum control valve 30.

The process gas supplied from the gas supply source 16 through a gas inflow port 11a or the purge gas supplied from the N₂ supply source 17 is supplied to the vacuum chamber 11 at a predetermined flow rate. Herein, the predetermined flow rate of the process gas represents a flow rate for actually performing pressure control of the vacuum chamber 11, namely a flow rate of the process gas that is required for deposition on the wafer 150.

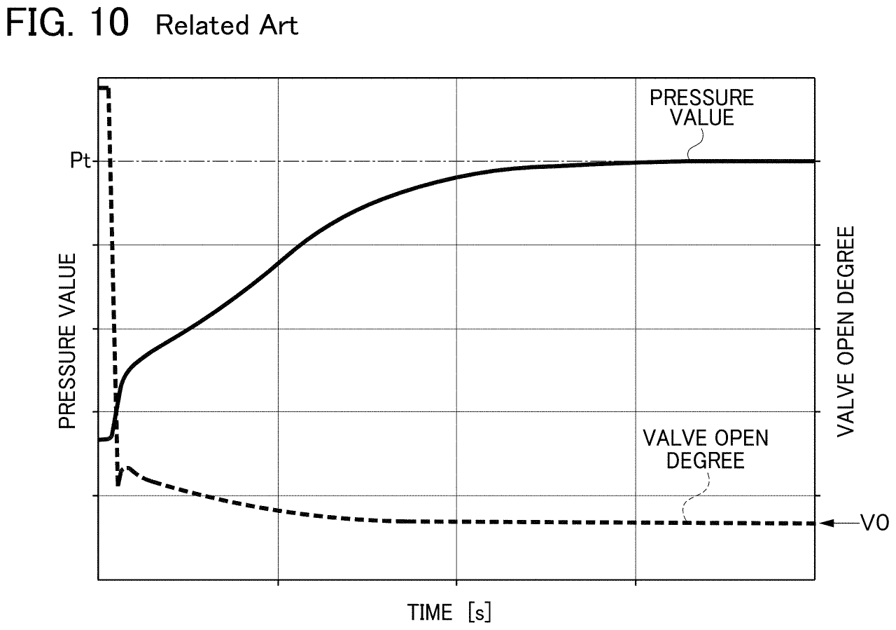

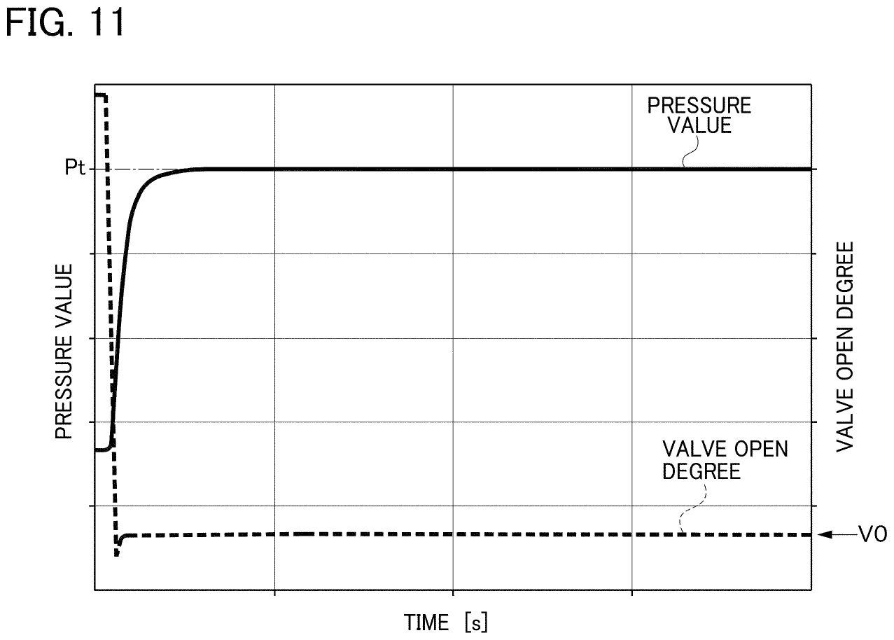

To a gas discharge port 11b of the vacuum chamber 11, a first port 41a of the vacuum control valve 30 is connected and to a second port 41b of the vacuum control valve 30, the vacuum pump 15 is connected. Thus, the process gas or the purge gas supplied to the vacuum chamber 11 is allowed to be taken in by the vacuum pump 15. At this time, the controller 70 obtains a pressure value inside the vacuum chamber 11 from the pressure sensor 12 and adjusts the valve open degree of the vacuum control valve 30 to perform the pressure value control of making the pressure value in the vacuum chamber 11 agree with a target value Pt. The valve open degree of the vacuum control valve 30 required for making the pressure value of the vacuum chamber 11 agree with the target value Pt is defined as an optimum valve open degree VO (see FIGS. 10 and 11).

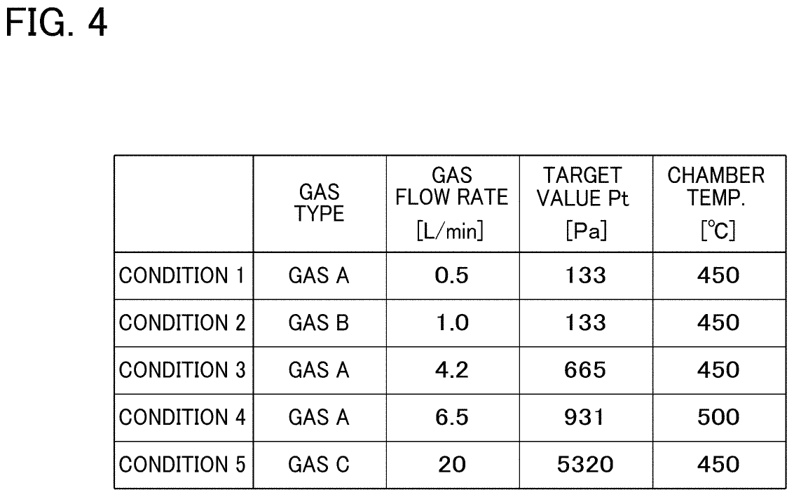

The vacuum pressure control system 1 having the above-mentioned configuration carries out the deposition in one process under a plurality of conditions. A plurality of the conditions are, for example, indicated as conditions 1 to 5 in a table of FIG. 4. A “gas type” indicated in FIG. 4 represents a type of the process gas used for deposition. In FIG. 4, specific types of the gas are not indicated, but the types are simply indicated as gas A, gas B, and gas C. A “gas flow rate” represents a flow rate (a predetermined flow rate) of the process gas which is required for deposition. The gas flow rate is regulated by the mass flow controller 20 and supplied to the vacuum chamber 11 at the flow rate indicated in FIG. 4. A “target value” represents the target value Pt of the pressure value inside the vacuum chamber 11. The controller 70 adjusts the valve open degree of the vacuum control valve 30 so that the pressure value agrees with this target value Pt. A “chamber temperature” represents a temperature inside the vacuum chamber 11. Under each of the conditions, purging by N₂ gas is carried out.

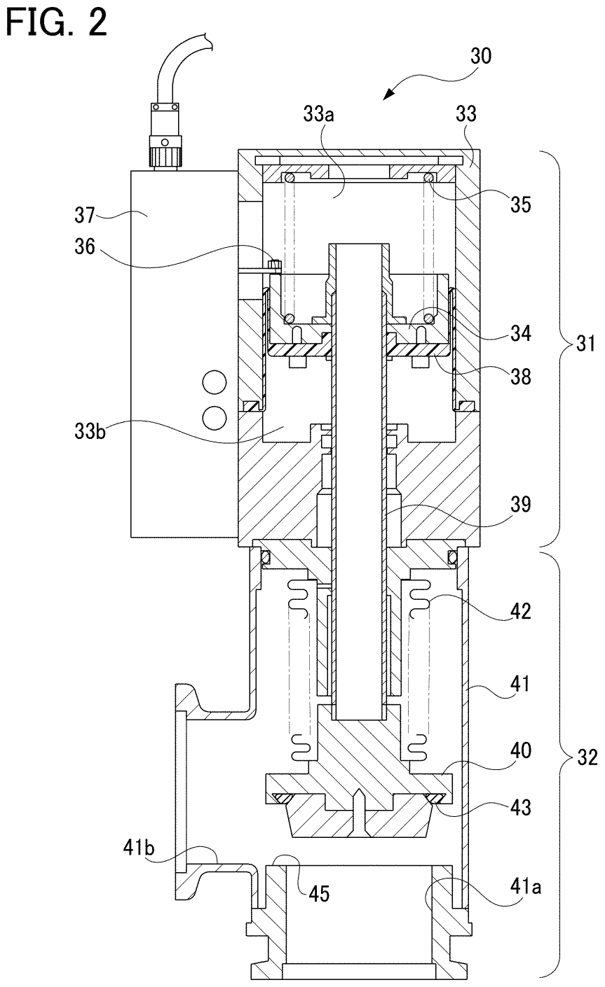

FIG. 2 is a sectional view of the vacuum control valve 30 which is in a fully-open state. The vacuum control valve 30 is provided with an air-pressure cylinder 31 and a bellows-type poppet valve 32 assembled one on another in the figure.

The air-pressure cylinder 31 includes a cylinder body 33 having a hollow cylinder chamber and a piston 34 slidably assembled in the cylinder chamber in a direction parallel (in an up and down direction in the figure) to a stacking direction of the air-pressure cylinder 31 and the bellows-type poppet valve 32. The piston 34 is urged downward by a restoring spring 35. On an upper end of the piston 34, a slide lever 36 extending upward is provided.

A potentiometer 37 as an open degree sensor is attached on an outside of the cylinder body 33. The potentiometer 37 is embedded with a variable resistor (not shown) connected to the slide lever 36. Integral upward and downward movement of the slide lever 36 with the piston 34 leads to changes in a variable resistance value, and the potentiometer 37 outputs this resistance value as a correlated value to a position of the piston 34 in a vertical direction to the controller 70.

A bellofram 38 is provided on a lower surface of the piston 34. The bellofram 38 is fixed to the piston 34 on its inner peripheral edge, and an outer peripheral edge of the bellofram 38 is fixed to an inner wall of the cylinder chamber. The bellofram 38 is extremely thin, and its structure is formed of strong polyester, tetoron cloth or the like covered thereon with rubber. The bellofram 38 has long deformation strokes and deep folding portions. The bellofram 38 of a cylindrical shape is a diaphragm having a uniform and unchanged effective pressure-receiving area during its deformation. The cylinder chamber includes an atmosphere chamber 33a and a pressurizing chamber 33b which are partitioned in an upper and lower direction by the piston 34 and the bellofram 38. The atmosphere chamber 33a on an upper side accommodates the restoring spring 35 and is introduced with the atmosphere from a not-shown atmospheric port. The pressurizing chamber 33b on a lower side is introduced with compression air from a not-shown air supply source through a not-shown pressurizing port.

In a center portion of the piston 34, a piston rod 39 inserted inside the bellows-type poppet valve 32 is fixed. The bellows-type poppet valve 32 is provided with the piston rod 39, a valve element 40, and a casing accommodating the piston rod 39 and the valve element 40. The valve element 40 is fixed to an end portion of the piston rod 39 on a side where the piston rod 39 is inserted in the bellows-type poppet valve 32. The casing 41 of a cylindrical shape includes the above-mentioned first port 41a and the second port 41b. On an upper surface of the valve element 40, a bellows 42 is provided. The bellows 42 is placed to enclose the piston rod 39.

The valve element 40 is provided with an O ring 43 on its lower surface, and on an upper end side of the first port 41a of the casing 41, a valve seat 45 to be into and out of contact with the valve element 40 is provided. When the valve element 40 is moved toward the valve seat 45 to be brought into contact with the valve seat 45, the 0 ring 43 is under a state of being pressed by the valve element 40 and the valve seat 45. Specifically, this state is a valve-fully-closed state of the vacuum control valve 30, and the flow of the process gas is shut off at this time.

Further, upward and downward movement of the piston 34 brings upward and downward movement of the valve element 40 via the piston rod 39. Thus, an open degree of the vacuum control valve 30 is changed. The potentiometer 37 then measures a position of the piston 34 in a vertical direction, and further a position of the valve element 40 in the vertical direction, which stands for the valve open degree of the vacuum control valve 30, and the potentiometer 37 outputs the thus measured value to the controller 70.

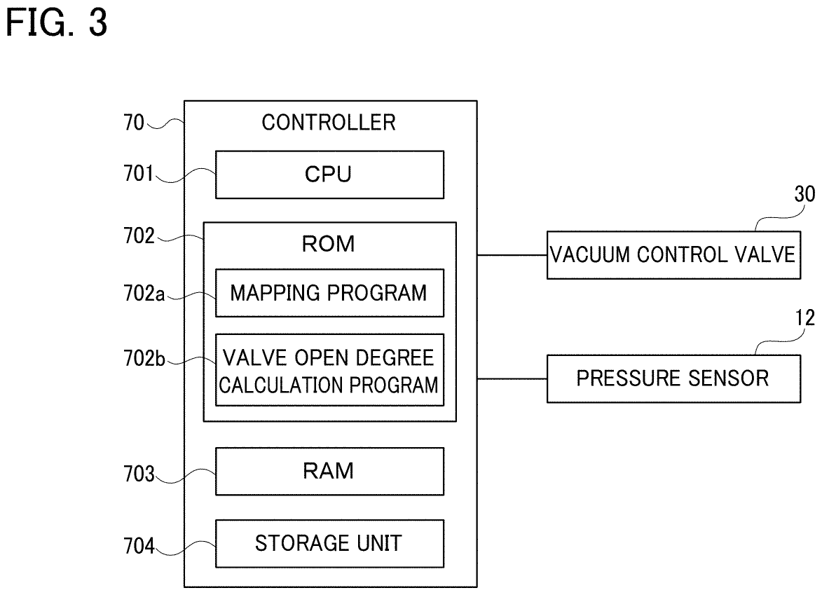

As shown in FIG. 3, the controller 70 includes a CPU 701, an ROM 702, an RAM 703, and a storage unit 704. The ROM 702 is stored with a mapping program 702a for forming a map used for calculating the optimum valve open degree VO and a valve-open-degree calculation program 702b for calculating the optimum valve open degree VO of the vacuum control valve 30 based on the formed map and then controlling the valve open degree of the vacuum control valve 30 to be the optimum valve open degree VO. The CPU 701 temporarily stores data to the RAM 703 and controls operation of the vacuum control valve 30 according to the mapping program 702a or the valve-open-degree calculation program 702b. Further, the storage unit 704 stores the map formed by the mapping program 702a.

### <Operation of Vacuum Pressure Control System>

Operation of the above-configured vacuum pressure control system 1 is explained with the vacuum pressure control system 1 in a case that a deposition process on the wafer 150 is to be performed according to the conditions 1 to 5 indicated in the table of FIG. 4, for example.

In advance of performing an actual pressure control for the deposition process, the vacuum pressure control system 1 calculates the optimum valve open degree VO of the vacuum control valve 30 under each of the conditions 1 to 5 by the mapping program 702a and the valve-open-degree calculation program 702b.

Firstly, the controller 70 forms a map used for calculating the optimum valve open degree VO by the mapping program 702a.

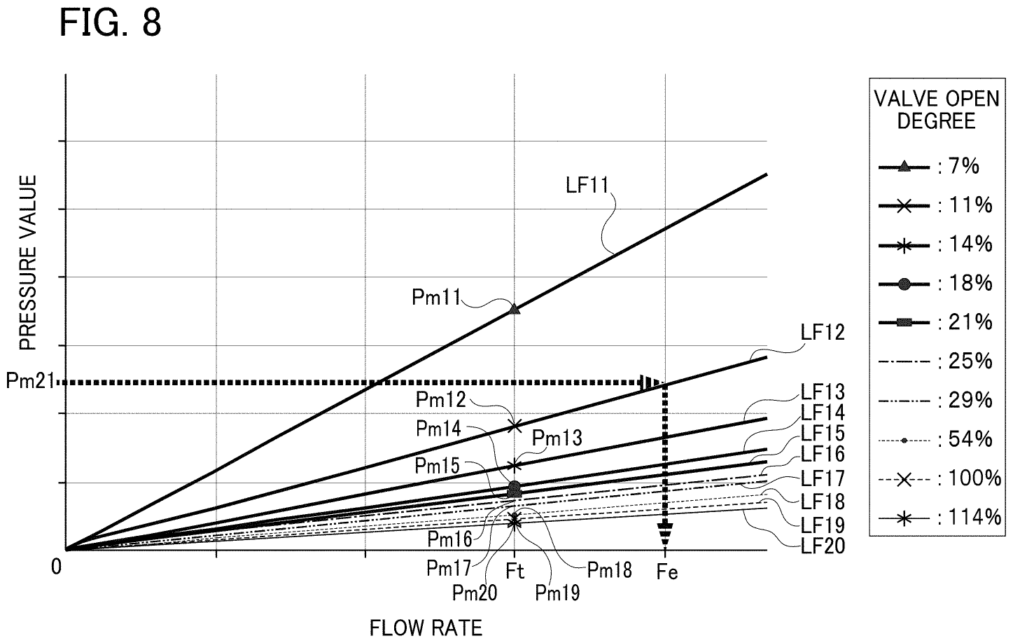

When the map is to be formed, an operator operates the system to supply the process gas to the vacuum chamber 11 at a measurement flow rate Ft (see FIG. 8) that is a flow rate for performing the mapping operation. The measurement flow rate Ft is a flow rate that has been predetermined by the mapping program 702a and is set as a value close to the actual supply amount of the process gas such as 10 L/min.

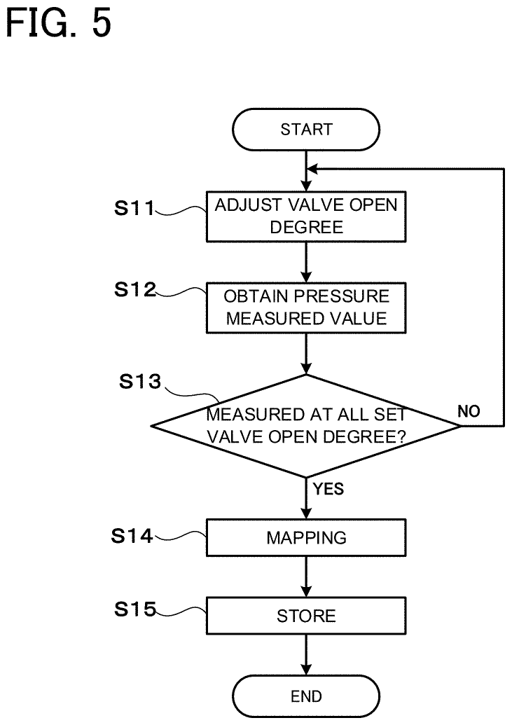

The mapping program 702a gets started while the gas at the measurement flow rate Ft is being supplied. The controller 70 adjusts the valve open degree of the vacuum control valve 30 to the predetermined valve open degree (S11 in FIG. 5). The valve-open-degree adjustment is controlled based on a resistance value which is output from the potentiometer 37.

Herein, the predetermined valve open degree represents a valve open degree that has been predetermined for formation of the map, and a plurality of the valve open degrees have been set. For example, on condition that the maximum valve open degree is set at 100%, valve open degrees of 7%, 11%, 14%, 18%, 21%, 25%, 29%, 54%, 100%, and 114% are set (see FIG. 8). In the present embodiment, the valve open degree is firstly adjusted as 7%.

After the valve open degree is adjusted to the predetermined degree, the controller 70 obtains a pressure measured value Pm11 of the vacuum chamber 11 from the pressure sensor 12 in a state in which the process gas is supplied at the measurement flow rate Ft, and then the controller 70 stores the value Pm11 (S12).

Subsequently, in all the remaining predetermined valve open degrees (11%, 14%, 18%, 21%, 25%, 29%, 54%, 100%, and 114%), the process is repeated until pressure measured values Pm12 to Pm20 are obtained (S13: NO).

After the pressure measured values of the vacuum chamber 11 at all the valve open degrees are obtained (S13: YES), the controller 70 carries out the map formation (S14). To be specific, at each of a plurality of the predetermined valve open degrees (7%, 11%, 14%, 18%, 21%, 25%, 29%, 54%, 100%, and 114%), the pressure measured values Pm11 to Pm20 are plotted to calculate the linear functions LF11 to LF20 with defining an intercept as zero through which the plotted pressure measured values Pm11 to Pm20 pass.

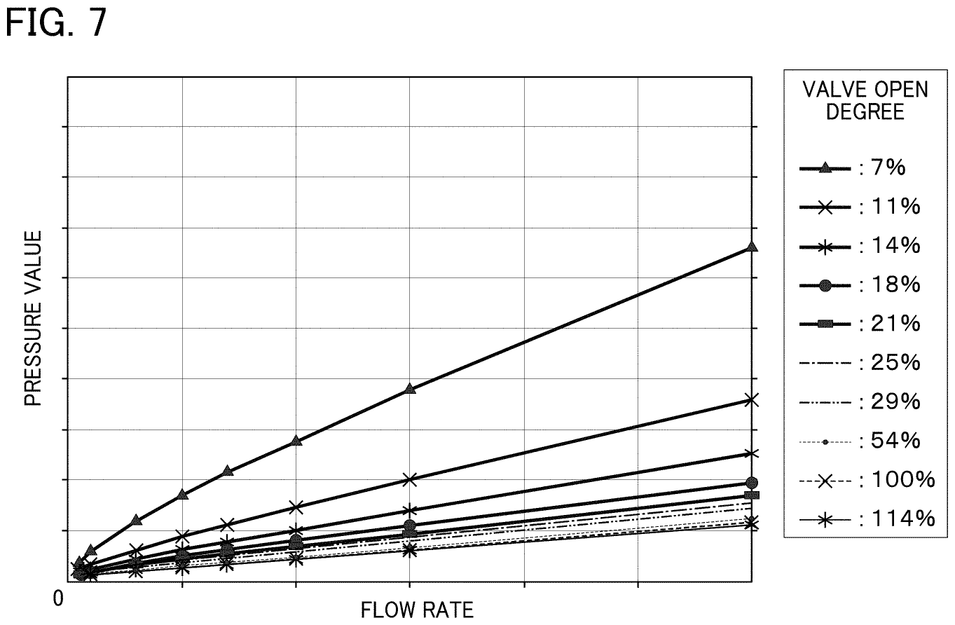

The linear functions LF11 to LF20 are plotted by approximating the relation between the pressure value in the vacuum chamber 11 and the flow rate of the process gas. This approximation is possible because the pressure value inside the vacuum chamber 11 increases according to an increase in the flow rate of the process gas as shown in FIG. 7 when the flow rate of the process gas is increased in a state in which the valve open degree of the vacuum control valve 30 is fixed to 7%, for example. This applies to any valve open degree of the vacuum control valve 30 (for example, the pressure value similarly increases at the valve open degrees of 11%, 14%, 18%, 21%, 25%, 29%, 54%, 100%, and 114% as shown in FIG. 7). As long as the valve open degree of the vacuum control valve 30 is constant, the pressure value of the vacuum chamber 11 increases as the flow rate of the process gas increases, and the pressure value decreases as the flow rate of the process gas decreases. In other words, the pressure value of the vacuum chamber 11 and the flow rate of the process gas is confirmed to be expressed by a proportional relation. Therefore, the relation between the pressure value of the vacuum chamber 11 and the flow rate of the process gas can be approximated to the linear functions LF11 to LF20 with the intercept of zero.

When the map formation is completed, the controller 70 stores the thus formed map in the storage unit 704 (S15), and the mapping program 702a is ended.

Next, an operation of calculating the optimum valve open degree VO of the vacuum control valve 30 by the valve-open-degree calculation program 702b under each one of conditions 1 to 5 in FIG. 4 is explained.

The optimum valve open degree VO under the condition 1 is calculated first.

In calculating the optimum valve open degree VO, an operator firstly operates the system to be in a condition that the process gas is supplied at a predetermined flow rate to the vacuum chamber 11. This predetermined flow rate indicates each gas flow rate that has been defined in the respective conditions 1 to 5. In the condition 1, the predetermined flow rate is 0.5 L/min as shown in FIG. 4.

After the process gas is being supplied at the predetermined flow rate, the operator operates the valve-open-degree calculation program 702b.

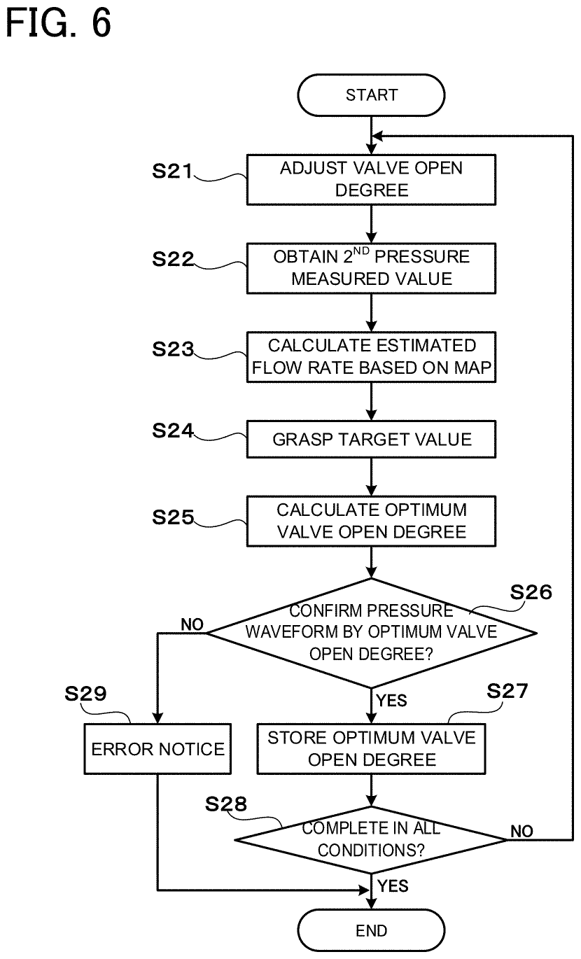

The controller 70 adjusts the valve open degree of the vacuum control valve 30 to any one of a plurality of predetermined valve open degrees (7%, 11%, 14%, 18%, 21%, 25%, 29%, 54%, 100%, and 114%) (see FIG. 6, S21). The operator can thus choose any one of a plurality of the predetermined valve open degrees before operating the valve-open-degree calculation program 702b. Herein, it is premised that a valve open degree of 11% is chosen as one example, and thus the controller 70 adjusts the valve open degree of the vacuum control valve 30 to 11%.

Subsequently, the controller 70 obtains a second pressure measurement value Pm21 by the pressure sensor 12 (S22).

After obtaining the second pressure measurement value Pm21, the controller 70 calculates an estimated flow rate Fe based on the map (S23). For example, when the vacuum control valve 30 is set at the valve open degree of 11%, Pm21 is substituted in the linear function LF12, so that the estimated flow rate Fe can be calculated.

The estimated flow rate Fe represents a flow rate of the process gas supplied to the vacuum chamber 11 and is equivalent to the predetermined flow rate (under the condition 1, the flow rate of 0.5 L/min). The estimated flow rate Fe equivalent to the predetermined flow rate is calculated because the vacuum control valve 30 cannot obtain information about the flow rate from the mass flow controller 20. Further, for obtaining the information about the flow rate from the mass flow controller 20 by the vacuum control valve 30, there is a need to configure a new circuit configuration, which could cause high costs, but as mentioned above, the controller 70 itself can calculate the flow rate as the estimated flow rate Fe, so that it becomes possible to obtain the information about the flow rate with the existing circuit configuration, which can achieve cost saving.

Subsequently, the controller 70 grasps the target value Pt of the pressure value in the vacuum chamber 11 (S24). The target value Pt is 133 Pa under the condition 1.

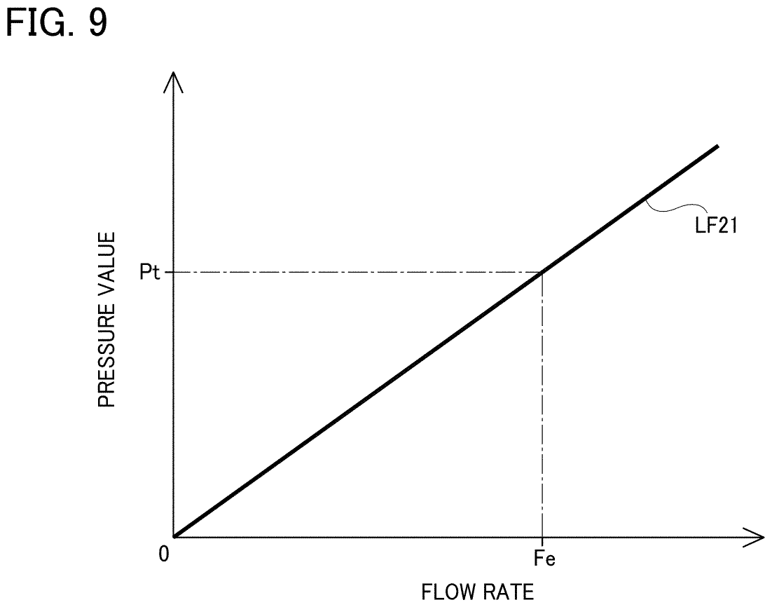

Based on the target value Pt and the estimated flow rate Fe, the optimum valve open degree VO is then calculated (S25). The relation between the pressure value and the flow rate can be approximated to the linear function, and accordingly, the target value Pt can be represented by the linear function LF21 of the estimated flow rate Fe with the intercept as zero as shown in FIG. 9. By obtaining an orientation of the linear function LF21, it is possible to obtain the optimum valve open degree VO of the vacuum control valve 30 suitable for making the pressure value in the vacuum chamber 11 agree with the target value Pt at the estimated flow rate Fe, namely at the predetermined flow rate from the thus obtained orientation.

The controller 70 subsequently confirms that the pressure value in the vacuum chamber 11 actually agrees with the target value Pt by the calculated optimum valve open degree VO (S26). Specifically, as shown in FIG. 11, the controller 70 observes a pressure waveform to confirm whether the pressure value of the vacuum chamber 11 actually agrees with the target value Pt with assuming that the valve open degree of the vacuum control valve 30 is the optimum valve open degree VO. The conventional technique requires operation of searching the optimum valve open degree VO as shown in FIG. 10, but the optimum valve open degree VO can be calculated as mentioned above, thus requiring no searching operation of the optimum valve open degree VO.

When it is confirmed that the pressure value reaches the target value Pt by the pressure waveform (S26: YES), the controller 70 stores the obtained optimum valve open degree VO to the storage unit 704 (S27). When the pressure value disagrees with the target value Pt from the result of confirming the pressure waveform, the controller 70 gives an error notification (S29), and then the valve-open-degree calculation program 702b is ended.

As mentioned above, the controller 70 repeats the process from S21 to S25 under all the conditions 1 to 5 (S28: NO) and obtains the optimum valve open degree VO under the respective conditions. After completion of the process through S21 to S27 under all the conditions 1 to 5 (S28: YES), the valve-open-degree calculation program 702b is ended.

When the actual deposition process is to be performed, the controller 70 reads out the optimum valve open degree VO from the storage unit 704 under each of the conditions, for example, reading out the optimum valve open degree VO of the condition 1 when performing deposition under the condition 1 and reading out the optimum valve open degree VO of the condition 2 when performing deposition under the condition 2 so that the valve open degree of the vacuum control valve 30 is adjusted to the optimum valve open degree VO. Thus, it is possible to control the pressure value in the vacuum chamber 11 to be the target value Pt.

Further, there is a case when a plurality of semiconductor manufacturing apparatuses of an identical type are installed in a plant, and in that case, only any one of a plurality of the semiconductor manufacturing apparatuses may have to be formed with a map by the mapping program 702a, so that the optimum valve open degree VO of the vacuum control valve 30 required for making the pressure value of the vacuum chamber 11 agree with the target value Pt can be calculated. Therefore, there is less possibility of taking time for advance preparation before performing the deposition process to cause a bad influence on a semiconductor manufacturing efficiency.

As mentioned above, the vacuum pressure control system 1 of the present embodiment is configured such that (1) the vacuum pressure control system 1 comprises: a gas supply source 16; a vacuum chamber 17 configured to receive supply of process gas from the gas supply source 16; a vacuum control valve 30 configured to adjust a pressure value in the vacuum chamber 11; and a vacuum pump 15 configured to decompress the vacuum chamber 11, which are connected in series, the vacuum pressure control system 1 further comprises: a pressure sensor 12 configured to detect the pressure value in the vacuum chamber 11; and a controller 70 configured to control the vacuum control valve 30, the vacuum pressure control system 1 configured to perform pressure value control of making the pressure value in the vacuum chamber 11 agree with a target value Pt by the controller 70 adjusting a valve open degree of the vacuum control valve 30 based on the pressure value detected by the pressure sensor 12 while the gas is supplied at a predetermined flow rate from the gas supply source 16 to the vacuum chamber 11, wherein the controller 70 comprises a mapping program 702a and a valve-open-degree calculation program 702b and is configured in advance of performing the pressure value control to: approximate a relation of the pressure value in the vacuum chamber 11 and the gas flow rate to linear functions LF11 to LF20 and storing the linear functions LF11 to LF20 in the controller 70 according to the mapping program 702a; and calculate an optimum valve open degree VO of the vacuum control valve 30 which is necessary for making the pressure value in the vacuum chamber 11 agree with the target value Pt when the gas at the predetermined flow rate is supplied based on the linear functions LF11 to LF20 according to the valve-open-degree calculation program 702b, and thus the controller adjusts the valve open degree of the vacuum control valve 30 based on the optimum valve open degree VO to make the pressure value in the vacuum chamber 11 agree with the target value Pt.

According to the vacuum pressure control system 1 in the above (1), the optimum valve open degree VO of the vacuum control valve 30 necessary for making the pressure value in the vacuum chamber 11 agree with the target value Pt can be easily calculated.

The controller 70 includes the mapping program 702a and the valve-open-degree calculation program 702b. According to the mapping program 702a, the relation of the pressure value in the vacuum chamber 11 and the flow rate of the process gas is approximated to the linear functions LF11 to LF20 and the linear functions LF11 to LF20 are stored in the controller 70. Then, based on the thus stored linear functions LF11 to LF20, the valve-open-degree calculation program 702b calculates the optimum valve open degree VO necessary for making the pressure value in the vacuum chamber 11 agree with the target value Pt when the process gas at the predetermined flow rate is supplied, and thus the valve open degree of the vacuum control valve 30 can be adjusted based on the calculated optimum valve open degree VO.

The relation of the pressure value in the vacuum chamber 11 and the flow rate of the process gas is approximated to the linear functions LF11 to LF20, and thus the optimum valve open degree VO can be calculated from the linear functions LF11 to LF20. Accordingly, in a case of performing deposition under plural conditions such as use of several types of the process gas, there is no need to adjust the valve open degree of the vacuum control valve 30 by experimentally supplying the process gas at a flow rate required for the deposition to the vacuum chamber 11 under each of the plural conditions (the conditions 1 to 5) and to search the optimum valve open degree VO that allows the pressure value of the vacuum chamber 11 to agree with the target value Pt. Therefore, there is less possibility of taking time for advance preparations prior to a deposition process, which could cause a bad influence on the semiconductor manufacturing efficiency.

Herein, the predetermined flow rate represents a flow rate of the process gas when the pressure control of the vacuum chamber 11 is actually carried out, and for example, indicates a flow rate of the process gas necessary for deposition on the wafer 150.

(2) In the vacuum pressure control system 1 described above in (1), in advance of performing the pressure value control, the mapping program 702a includes: obtaining a pressure measured values Pm11 to Pm20 of the vacuum chamber 11 at a predetermined valve open degree by the pressure sensor 12 in a state in which the process gas is supplied at a measurement flow rate determined by the mapping program 702a to the vacuum chamber 11 from the gas supply source 16 while the vacuum control valve 30 opens at the predetermined valve open degree, and gaining the linear functions LF11 to LF20, which is formed with an intercept as zero and extending through the pressure measurement values Pm11 to Pm20 at the predetermined valve open degree, based on the measurement flow rate and the pressure measured values Pm11 to Pm20.

According to the vacuum pressure control system 1 described in the above (2), the optimum valve open degree VO of the vacuum control valve 30 necessary for making the pressure value of the vacuum chamber 11 agree with the target value Pt can be easily calculated.

When the valve open degree of the vacuum control valve 30 is uniform, the more the flow rate of the process gas increases, the higher the pressure value in the vacuum chamber 11 becomes, and on the other hand, the lower the flow rate of the process gas is, the lower the pressure value becomes. Namely, the pressure value of the vacuum chamber 11 and the flow rate of the process gas are in a proportional relation. Accordingly, the relation of the pressure value inside the vacuum chamber 11 and the flow rate of the process gas can be approximated to the linear functions LF11 to LF20 (an orientation of the function depends on the predetermined valve open degree) with an intercept as zero, and thus use of these linear functions LF11 to LF20 achieves easy calculation of the optimum valve open degree VO of the vacuum control valve 30 necessary for making the pressure value of the vacuum chamber 11 agree with the target value Pt.

Further, in a plant, there may be provided a plurality of semiconductor manufacturing apparatuses of the same type. Only any one of those semiconductor manufacturing apparatuses has to obtain the above linear functions LF11 to LF20, so that semiconductor manufacturing apparatuses of the same type can calculate the optimum valve open degree VO of the vacuum control valve 30, which is necessary for making the pressure value of the vacuum chamber 11 agree with the target value Pt, by use of the common linear functions LF11 to LF20 in the semiconductor manufacturing apparatuses of the same type. Accordingly, there is less possibility of taking time for advance preparations prior to the deposition process and less possibility of giving a bad influence on the semiconductor manufacturing efficiency.

(3) In the vacuum pressure control system 1 described in the above (1) or (2), in advance of performing the pressure value control, the valve-open-degree calculation program 702b includes: obtaining a second pressure measured value Pm21 in the vacuum chamber 11 by the pressure sensor 12 in a state in which the process gas at the predetermined flow rate is supplied to the vacuum chamber 11 at the predetermined valve open degree; calculating an estimated flow rate Fe of the process gas by substituting the second pressure measured value Pm21 into the linear functions LF11 to LF20; and gaining an orientation of the linear function LF21 with the target value Pt set as a linear function LF21 of the estimated flow rate Fe with an intercept as zero and gaining the optimum valve open degree VO at the predetermined flow rate from the orientation.

According to the vacuum pressure control system 1 described in the above (3), the optimum valve open degree VO of the vacuum control valve 30, which is necessary for making the pressure value in the vacuum chamber 11 agree with the target value Pt, can be easily calculated.

Each orientation of the linear functions LF11 to LF20 has been determined by the predetermined valve open degree, and the second pressure measured value Pm21 under a state in which the process gas at the predetermined flow rate is being supplied to the vacuum chamber 11 is substituted into the linear functions LF11 to LF20. Thus, the calculated estimated flow rate Fe is equivalent to the predetermined flow rate.

The relation of the pressure value inside the vacuum chamber 11 and the flow rate of the process gas has been confirmed to be approximated to the linear function with the intercept of zero, and thus the target value Pt is a function (the linear function LF21) of the estimated flow rate Fe that is equivalent to the predetermined flow rate, so that the orientation of the linear function LF21 can be calculated. This orientation represents the optimum valve open degree VO for obtaining the target value Pt at the predetermined flow rate.

The estimated flow rate Fe equivalent to the predetermined flow rate is calculated by the controller 70 itself, thus requiring no need to input information about the predetermined flow rate by an external device and performing calculation of the optimum valve open degree VO. Therefore, there is no need to newly configure an apparatus for inputting information about the predetermined flow rate to the vacuum control valve 30 and the controller 70, and it is possible to calculate the optimum valve open degree VO of the vacuum control valve 30 by a conventional equipment.

The above embodiment is only an illustration and has no any limitation to the present disclosure. Accordingly, the present disclosure may be made with any improvements and modifications without departing from the scope of the disclosure.

For example, the above embodiment raises ten valve open degrees of 7%, 11%, 14%, 18%, 21%, 25%, 29%, 54%, 100%, and 114% as the predetermined valve open degree for a map formation according to the mapping program 702a. However, the valve open degree is not limited to the above, and may be any valve open degrees and not limited to ten types.

### REFERENCE SIGNS LIST

1 Vacuum pressure control system
11 Vacuum chamber
12 Pressure sensor
15 Vacuum pump
16 Gas supply source
30 Vacuum control valve
70 Controller

What is claimed is:

1. A vacuum pressure control system comprising:
a gas supply source;
a vacuum chamber configured to receive supply of gas from the gas supply source;
a vacuum control valve configured to adjust a pressure value in the vacuum chamber; and
a vacuum pump configured to decompress the vacuum chamber, which are connected in series,
the vacuum pressure control system further comprising:
a pressure sensor configured to detect the pressure value in the vacuum chamber; and
a controller configured to control the vacuum control valve,
the vacuum pressure control system configured to perform pressure value control of making the pressure value in the vacuum chamber agree with a target value by the controller adjusting a valve open degree of the vacuum control valve based on the pressure value detected by the pressure sensor while the gas is supplied at a predetermined flow rate from the gas supply source to the vacuum chamber, wherein
the controller comprises a mapping program and a valve-open-degree calculation program and is configured in advance of performing the pressure value control to:
approximate a relation of the pressure value in the vacuum chamber and the gas flow rate to a linear function and storing the linear function in the controller according to the mapping program; and
calculate an optimum valve open degree of the vacuum control valve which is necessary for making the pressure value in the vacuum chamber agree with the target value when the gas at the predetermined flow rate is supplied based on the linear function according to the valve-open-degree calculation program, and
the controller adjusts the valve open degree of the vacuum control valve based on the optimum valve open degree to make the pressure value in the vacuum chamber agree with the target value.

2. The vacuum pressure control system according to claim 1, wherein,
in advance of performing the pressure value control, the mapping program includes:
obtaining a pressure measured value of the vacuum chamber at a predetermined valve open degree by the pressure sensor in a state in which the gas is supplied at a measurement flow rate determined by the mapping program to the vacuum chamber from the gas supply source while the vacuum control valve opens at the predetermined valve open degree, and
gaining the linear function, which is formed with an intercept as zero and extending through the pressure measurement value at the predetermined valve open degree, based on the measurement flow rate and the pressure measured value.

3. The vacuum pressure control system according to claim 1, wherein
in advance of performing the pressure value control, the valve-open-degree calculation program includes:
obtaining a second pressure measured value in the vacuum chamber by the pressure sensor in a state in which the gas at the predetermined flow rate is supplied to the vacuum chamber at the predetermined valve open degree;
calculating an estimated flow rate of the gas by substituting the second pressure measured value into the linear function; and
gaining an orientation of the linear function with the target value set as a linear function of the estimated flow rate with an intercept as zero and gaining the optimum valve open degree at the predetermined flow rate from the orientation.

4. The vacuum pressure control system according to claim 2, wherein in advance of performing the pressure value control, the valve-open-degree calculation program includes:
obtaining a second pressure measured value in the vacuum chamber by the pressure sensor in a state in which the gas at the predetermined flow rate is supplied to the vacuum chamber at the predetermined valve open degree;
calculating an estimated flow rate of the gas by substituting the second pressure measured value into the linear function; and
gaining an orientation of the linear function with the target value set as a linear function of the estimated flow rate with an intercept as zero and gaining the optimum valve open degree at the predetermined flow rate from the orientation.
